(19) United States
(12) Patent Application Publication
(10) Pub. No.: US 2003/0189424 A1
(43) Pub. Date: Oct. 9, 2003

(54) Method and apparatus for prevention of probe card damage, when used with a manual wafer prober

(76) Inventor: Robert E. Urstadt, Neshanic Station, NJ (US)

Correspondence Address: Robert Urstadt, 444 Whiton Road, Neshanic Station, NJ, 08853, US

(21) Appl. No.: 10/119,232

(22) Filed: Apr. 9, 2002

(51) Int. Cl. G01R 1/00

(52) U.S. Cl. 324/158.1

(57) ABSTRACT

Disclosed is a method and apparatus to protect probe cards and improve the capabilities of manual chip and wafer probers. Damage to the probe card and the wafer or chip can occur, when the wafer chuck is moved while the probe card is in the down or contact position. The main problem of damage occurs, on those probers, which have a “quick slide out carrier” on which the chuck X,Y stage is mounted. A “quick slide out carrier” is used for easy access and quick change of test chips or wafers. This safety mechanism is accomplished by a microswitch attached to the platen lift which activates an electromagnet or solenoid, which prevents pull-out of the “quick slide” assembly, if it is accidentally pulled out while the probe card and platen are in the down, contact position.

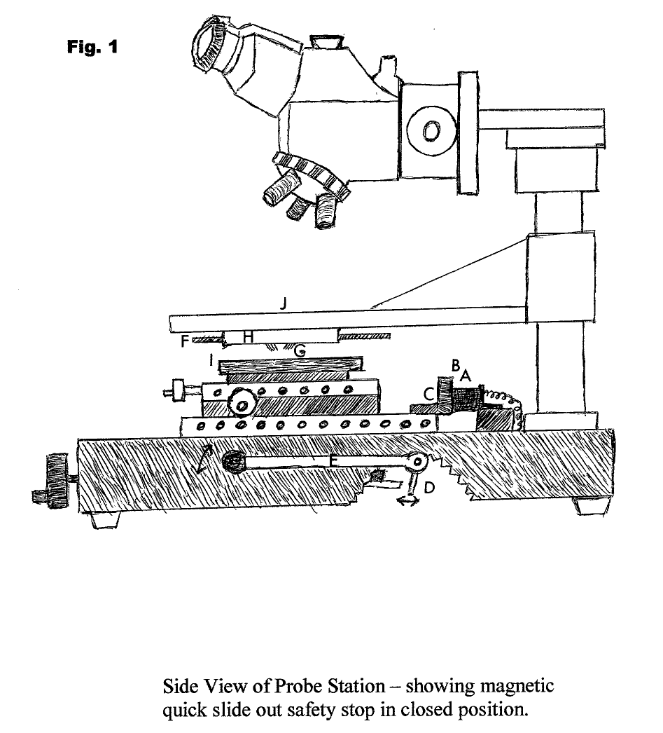

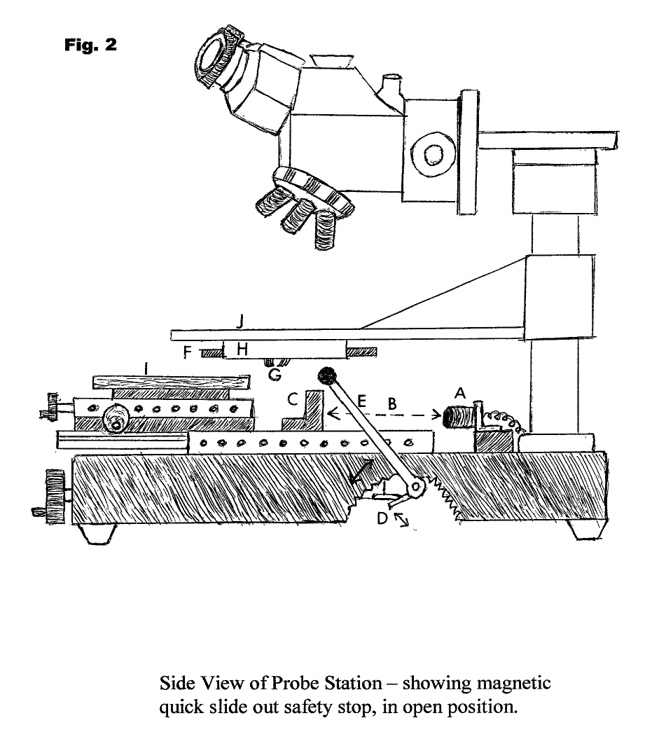

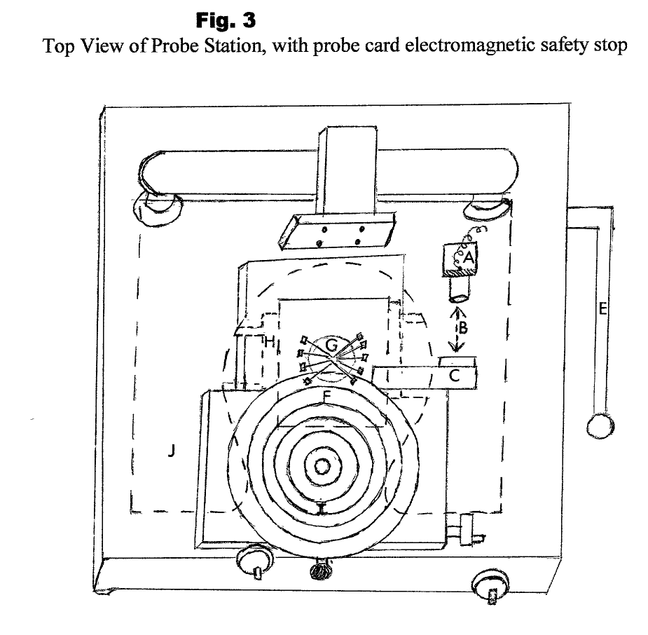

### BACKGROUND

Manual wafer or chip probe stations are frequently used for step and repeat types of usage with a probe card. This is acomplished by using the Platen quick lift to raise the probe card and move the wafer and then lower the probe card on the new location. Probe cards are often expensive and delivery is slow. Some manual wafer probers have a “quick pull out slider”. This is a slider/carrier, attached to the bottom of the chuck X,Y translation stage, to facilitate easy unload and reload of the chuck. The “quick pull out slider” usually pulls out in the Y direction. This feature, was introduced by Rucker and Kolls in 1968, on their #260 station. The most frequent damage to probe cards is as a result of accidental pull out of the “quick pull out slider”, while the probe card is in contact with the wafer or chip. On all analytical probers, the Platen holds the probe card by means of a probe card holder. When the Platen is in the down position, the probes are in contact with the wafer or chip. Any sudden and significant movement, such as pulling the chuck “quick slider” forward, will destroy the probe card. In the past the only solution to correct this, has been the use a software driven, more expensive Automatic or Semiautomatic prober which had electronic surface level sensing, as is described by Fergason U.S. Pat. No. 3,996,517

### SUMMARY OF THE INVENTION

It is therefore the purpose of this invention, to provide a simple Electromechanical, safety interlock which will prevent the prober user, from pulling out the “quick slide out Chuck carrier assembly”, while the probe card is in contact with the wafer or chip. This will protect against the most prevalent accidental damage to probe cards.

### References Cited

### U.S. Patent Documents

U.S. Pat. No. 3,996,517 Dec. 7, 1976 Fergason et. al. 324/754

### DESCRIPTION OF DRAWINGS Drawing Number 1. Shows a side view of the prober, as seen from the right side.

A. Is an electromagnet, which is mounted to the rear of the base of the prober.

B. Is showing the Chuck “quick pull out slider” in the closed position and the platen lever in the down position, which activates the electromagnet and locks the “quick pull out slide, in place.

C. Shows a magnetic steel block, which is attached to the “quick pull out slider” frame.

D. Shows a lever protruding from the transverse shaft of the “platen quick lift”, which will open a microswitch, when the platen quick lift lever #E. is raised.

E. Platen quick lift lever. This is attached to a lift mechanism, which raises the Platen and therefore the probe card ¼ inch high, in a one step lever lift movement. The platen stays at the “up” position until the lever is lowered.

F. The probe card is shown suspended from the platen #J. which would be in contact with the wafer or chip sitting on the Chuck I.

G. The probe card has contact probes in fixed positions, which contact pads on the wafer.

H. The probe card holder is attached to the platen.

I. The wafer or chip sits on the vacuum chuck

J. Platen: this is a large platform for mounting probe card holders or individual Manipulators with probes.

Drawing number #2. Is similar to drawing number #1—it shows the same side view, with all the same features and labels, but with the “quick pull out slider”in the open position and the stage carrier assembly pulled forward. The Platen Quick lift Lever #E. is in the up or passive position. In this position (the safe position)—with the platen up and the probe card lifted—the electromagnet is able to release the “quick pull out slider”.

Drawing Number #3. Is a top view of the probe station with the Microscope, platen and Probe card removed, to show a top view of the:

A: Electromagnet

B: “The quick pull out slider” is in the open position.

C. the Steel Block

D. The platen quick lift lever

E. The “quick pull out slider carrier”

F. Outline of Platen

G. Vacuum chuck Assembly

H. Y axis stage movement

I. X axis stage movement

J. Base of probe station

### DESCRIPTION OF INVENTION

This is a simple electromechanical assembly, designed to Facilitate the rapid load and unload of wafers or chips on manual prober, minimizing accidental damage of the probe card. This is accomplished by locking the “quick slide out” chuck carrier assembly, in place while a probe card is in contact with the wafer or chip, thereby protecting the wafer or chip. The system consists of an electromagnet which is mounted to the rear of the base of the prober, which comes in contact with a magnetic steel block which is attached to the Chassis of the “quick slide out assembly”. Attached to the underside of the base is a microswitch, which is opened and closed by a lever attached to the “platen quick lift” transverse shaft, inside the base.

Materials Used:

A 24v DC Electromagnet from AEC Magnetics of Cincinatti Ohio model 24C. This generates a 20 lb. Force. Heavier duty ones are available but not needed.

A #PSR 2/24 power supply from Spieco of Amityville N.Y.

An 8″ probe station with “quick pull out chuck carrier slider” from Creative Devices Inc. of Neshanic Sta. N.J.

1. This is designed for protection of Probe cards in those situations where a manual prober is being used for a step and repeat operation and there is a rapid change of wafers, chips or devices using a “quick slide out chuck carrier assembly”. In this case accidental damage to the probe card and wafer or chip, caused by pulling out the “quick slide” while the probe card is in contact with the wafer or chip, will be averted. An electromagnetic safety stop immobilizes the “quick slide”, while the platen and probe card are in the down/contact position and prevents the quick slide from being pulled out, until the platen and probe card are lifted.

2. For those situations such as low current testing, where an electromagnet Is not desirable, a pneumatic or solenoid plunger with mechanical stop Will achieve the same purpose.
